(19) United States
(12) Patent Application Publication
(10) Pub. No.: US 2024/0210835 A1
(43) Pub. Date: Jun. 27, 2024

(54) SYSTEM FOR EXPOSURE OF ULTRA-VIOLET LIGHT TO A PHOTORESIST DEVELOPER SOLUTION

(71) Applicant: Intel Corporation, Santa Clara, CA (US)

(72) Inventor: Joseph Bloxham, Laveen, AZ (US)

(73) Assignee: Intel Corporation, Santa Clara, CA (US)

(21) Appl. No.: 18/145,035

(22) Filed: Dec. 22, 2022

(51) Int. Cl. G03F 7/40; G03F 7/20; G03F 7/32

(52) U.S. Cl. CPC G03F 7/40; G03F 7/32; G03F 7/70058

(57) ABSTRACT

Systems, apparatuses, and methods related to reducing the degradation of recycled developer solution are disclosed herein. In some embodiments, an apparatus may include a developer chamber, a process tank including a developer solution, a delivery stream coupling the process tank and the developer chamber to flow developer solution from the process tank to the developer chamber, a return stream coupling the developer chamber and the process tank to flow developer solution from the developer chamber to the process tank; and a light source exposing the developer solution to UV light or white light, wherein the light source exposes the developer solution to UV light or white light in the process tank, in the return stream, or the delivery stream.

### TECHNICAL FIELD

The present disclosure relates to manufacturing integrated circuits (ICs). More specifically, it relates to techniques, methods, and apparatus directed to methods of extending a potency and efficacy of reused developer solution for photoresist patterning.

### BACKGROUND

Electronic circuits when commonly fabricated on a wafer of semiconductor material, such as silicon, using lithography. Such electronic circuits are called ICs. The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example system for recycling a developer solution according to some embodiments of the present disclosure.

FIG. 2 illustrates another example system for recycling a developer solution according to some embodiments of the present disclosure.

FIG. 3 is a schematic flow diagram listing example operations that may be associated with recycling a developer solution according to some embodiments of the present disclosure.

### DETAILED DESCRIPTION

For purposes of illustrating IC packages manufactured using photolithography described herein, it is important to understand phenomena that may come into play during developing a photoresist. The following foundational information may be viewed as a basis from which the present disclosure may be properly explained. Such information is offered for purposes of explanation only and, accordingly, should not be construed in any way to limit the broad scope of the present disclosure and its potential applications. An IC may be built on a silicon wafer made from a monocrystalline silicon boule. The typical manufacturing process for such ICs includes photolithography, etching, heat diffusion, oxidation, and other such processes to occur on the surface of the wafer, such that active circuit elements (e.g., transistors and diodes) are formed on the planar surface of the silicon wafer. In some instances, an IC similarly may be built on a panel.

A photoresist is typically a light-sensitive polymer or polymer precursor dissolved in one or more organic solvents. When exposed to light, a photoresist may be further polymerized or cross linked to form a hardened coating which is resistant to etching solutions (e.g., negative-type photoresist) or may become more easily decomposable or dissolvable (e.g., positive-type photoresist). A common example of a negative-type photoresist reaction utilizes methyl methacrylate which forms an insoluble polymer when exposed to ultraviolet (UV) light. In the positive-type photoresist case, the unexposed portions become hardened coatings resistant to etching solutions. UV light with a wavelength between 10 nanometers and 400 nanometers is generally used. A photoresist may be coated on a surface of a substrate, baked at a low temperature to remove solvent, then exposed to UV light through a mask corresponding to the pattern to be produced on the substrate. The mask selectively exposes areas of the photoresist to the UV light to create the pattern, which may be used as a guide for deposition of copper and other materials on the substrate. After exposure to light, the photoresist is developed by spraying or immersing the photoresist in a chemical solution, called a developer solution, which dissolves the unexposed portions of the photoresist (e.g., in the case of a negative-type photoresist) or the exposed portions (e.g., in the case of a positive-type photoresist). When a negative-type photoresist is used, the mask will have a negative image of the pattern to be produced, such that the pattern created is an opposite image of the mask used. When a positive-type photoresist is used, the areas exposed to ultraviolet light (e.g., the exposed/unmasked areas) degrade or decompose and are more easily removed. The remaining areas (e.g., the unexposed/masked areas) become resistant to the developer solution, such that the pattern created is a same image as the mask used.

Developing a photoresist after exposure to UV light may be crucial to maintaining circuit element tolerances. A photoresist may be underdeveloped or overdeveloped. An underdeveloped photoresist refers to a condition where the unpolymerized photoresist is not completely dissolved or removed so the underlying metal is not fully exposed and will not be etched away. An underdeveloped photoresist may result in circuit shorts. An overdeveloped photoresist may result in the developer solution undercutting the photoresist, which may cause the photoresist lifting away from and further expose the underlying metal resulting in decreased resolution and additional underlying metal to be etched away. An overdeveloped photoresist may result in open circuits. Although UV light is typically used in photoresist patterning, in some cases, white light, with a wavelength between 400 nanometers and 780 nanometers and having a requisite intensity, may be used to produce the reaction in the photoresist. A requisite intensity may be achieved, for example, by increasing total wattage, decreasing a distance between the white light source and the photoresist, and/or focusing the white light directly on the photoresist.

A photoresist may be deposited on a substrate, such as a panel or wafer. The photoresist may be deposited using any suitable technique, including lamination, atomic layer deposition (ALD), chemical vapor deposition (CVD), or physical vapor deposition (PVD). After UV light exposure, the panel and UV light-exposed photoresist may be placed in a developer chamber and sprayed or immersed in a developer solution to remove designated areas of photoresist from the panel. A developer solution is typically recycled and reused for multiple manufacturing processes and even over multiple days of manufacturing processes. When removing developed photoresist as part of a developer process, some of the developed photoresist may flow back into the recycled developer solution. The larger portions of the developed photoresist may be removed by filters, but smaller portions may not be removed and may continue to react with the recycled developer solution. Such a continued reaction may reduce the efficacy and potency of the recycled developer solution by consuming the active chemical ingredients. When a recycled developer solution loses potency, increased manufacturing defects and decreased yields may occur. Further, the recycled developer solution is likely to be discarded and replaced with fresh (e.g., unused or not recycled) developer solution more frequently, which increases manufacturing cost and developer solution consumption. Ways to mitigate the degradation of a recycled developer solution may be desired.

Accordingly, systems, apparatuses, and methods related to reducing the degradation of recycled developer solution are disclosed herein. In some embodiments, an apparatus may include a developer chamber, a process tank including a developer solution, a delivery stream coupling the process tank and the developer chamber to flow developer solution from the process tank to the developer chamber, a return stream coupling the developer chamber and the process tank to flow developer solution from the developer chamber to the process tank; and a light source exposing the developer solution to UV light or white light, wherein the light source exposes the developer solution to UV light or white light in the process tank, in the return stream, or in the delivery stream. In some embodiments, an apparatus may include a white light source, instead of a UV light source, that exposes the developer solution to white light.

Each of the systems, apparatuses, and methods of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The term “coupled” means either a direct connection (which may be one or more of a mechanical, electrical, and/or thermal connection) between the things that are connected, or an indirect connection through one or more intermediary objects between the things that are connected.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

In the drawings, a particular number and arrangement of components are presented for illustrative purposes and any desired number or arrangement of such components may be present in various embodiments.

For convenience, if a collection of reference numerals designated with different numerals are present (e.g., 110-1, 110-2, etc.), such a collection may be referred to herein without the numerals or letters (e.g., as “110”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

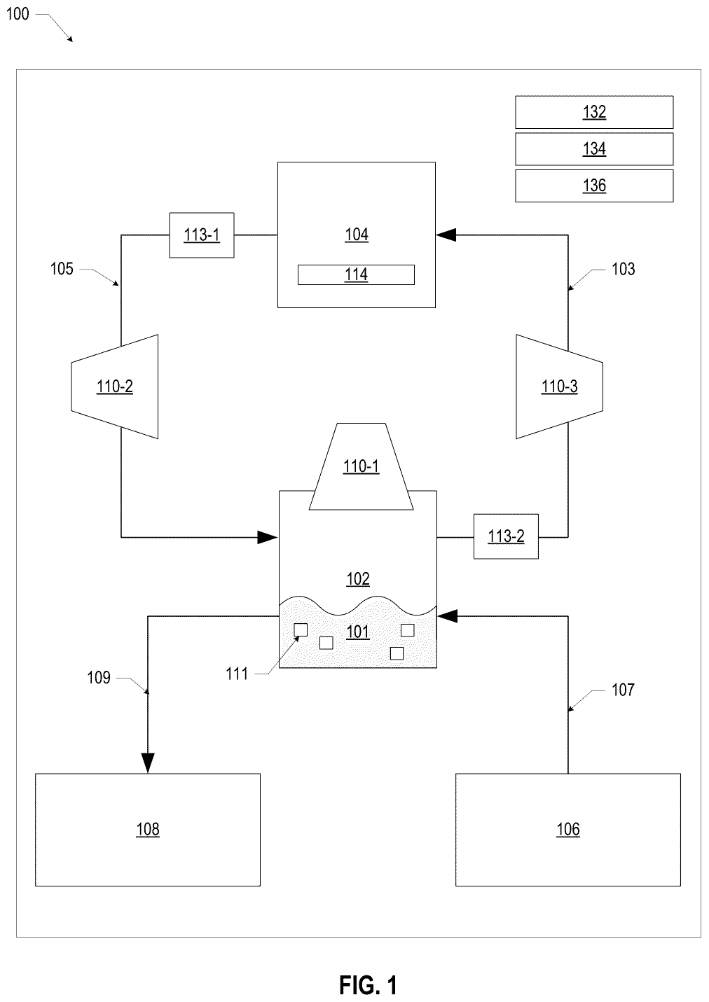

FIG. 1 illustrates an example system 100 for recycling developer solution according to some embodiments of the present disclosure. System 100 may include a process tank 102 including a developer solution 101, a developer chamber 104, a delivery stream 103 coupling the process tank 102 and the developer chamber 104, a return stream 105 coupling the developer chamber 104 and the process tank 102, and a UV light source 110 (e.g., UV light source 110-1) exposing the developer solution 101 to UV light in the process tank 102. A substrate 114 with a patterned photoresist may be placed in the developer chamber 104 for development (e.g., to remove or dissolve an exposed portion or an unexposed portion of the patterned photoresist depending on whether the photoresist is a positive or negative photoresist, as described above). A substrate 114 may include a semiconductor material, such as silicon, and may include a wafer or a panel. The developer chamber 104 may include support elements and/or other components (not shown) for placing and/or holding a substrate 114 during the development process. The developer solution 101 in the process tank 102 may be delivered to the developer chamber 104 by the delivery stream 103 for developing the patterned photoresist on the substrate 114. The developer solution 101 may be sprayed on the substrate 114 or the substrate 114 may be immersed in the developer solution in the developer chamber 104. Subsequent to the developing process, the developer solution 101 may be collected and returned to the process tank 102 by the return stream 105 for recycling (e.g., reuse). The recycled developer solution 101 may include removed portions of photoresist 111. The removed portions of photoresist 111 may continue to react with the developer solution 101, which consumes the active chemistry ingredients and degrades the efficacy and potency of the developer solution 101. By exposing the developer solution 101 with the removed portions of photoresist 111 to a UV light source 110, the removed portions of photoresist 111 become less reactive or even non-reactive, which may lessen the degradation of the developer solution 101.

A light source 110 may include any suitable UV light or white light source, including a lamp, an array of lamps, a string of lights, or a lamp within a container, that exposes a developer solution 101 with the removed portions of photoresist 111 to UV/white light (e.g., light source 110 is directed at the developer solution 101). In some embodiments, a light source 110 may include a combination of UV light and white light sources. In some embodiments, a system 100 may include multiple light sources 110 (e.g., light sources 110-1, 110-2, and 110-3). For example, as shown in FIG. 1, a system 100 may include a first light source 110-1 positioned to expose UV/white light to the developer solution 101 in the process tank 102, a second light source 110-2 positioned to expose UV/white light to the developer solution 101 in the return stream 105, and a third light source 110-3 positioned to expose UV/white light to the developer solution 101 in the delivery stream 103. The light sources 110 may be a same light source or may be different light sources. For example, the first, second, and third light sources 110-1, 110-2, 110-3, may be lamps or an array of lamps. In another example, the first light source 110-1 may be a lamp, and the second and third light sources 110-2, 110-3 may be a string of lights wrapped around the return stream 105 and the delivery stream 103, respectively, (e.g., where the streams 103, 105 include a clear tubing that is UV/white light compatible). The objective for a light source 110 is to provide sufficient UV/white light exposure to the developer solution 101 to minimize reactivity of portions of photoresist 111.

A system 100 may further include one or more filters 113 for removing larger pieces of the removed portions of photoresist 111. For example, in some embodiments, a filter 113-1 may be placed along the return stream 105 to collect the larger pieces of the removed portions of photoresist 111 before returning the developer solution 101 to the process tank 102. In some embodiments, a filter 113-2 may be placed along the delivery stream 103 to collect the larger pieces of the removed portions of photoresist 111 before delivering the developer solution 101 to the developer chamber 104. The filter 113 may help to reduce an overall amount of reactive portions of the removed photoresist, but will likely not remove all of the reactive portions of removed photoresist 111, especially the smaller pieces. Further, unlike the UV light source 110, the filter 113 will not inactivate the portions of removed photoresist 111. Although FIG. 1 shows a particular number and arrangement of filters 113, a system 100 may include any suitable number and arrangement of filters 113.

A system 100 may include a developer solution source vessel 106 that supplies pure (e.g., new and unused) developer solution 101 to the process tank 102 by a feed stream 107 and a developer solution waste vessel 108 that discards spent developer solution 101 by the waste stream 109. The developer solution source 106 and the developer solution waste 108 may be a continuous or semi-continuous process that adds pure solution and removes spent solution to maintain an efficacy or potency of the recycled developer solution 101. An efficacy or potency of a recycled developer solution 101 may be determined by measuring a concentration of the active ingredients. For example, a pH or conductivity of an active ingredient of the developer solution , such as sodium carbonate, may be measured to establish the concentration of the active ingredient.

A system 100 may include other devices for controlling and maintaining process parameters, such as a controller 132, a pump 134, and a heater/cooler 136, among others. A controller 132 may be programmed with instructions to turn the light source 110 on and off according to manufacturing parameters. For example, in some embodiments, the controller 132 may be programmed to turn the light source 110 on or off when the system 100 turns on or off; in other embodiments, the controller 132 may be programmed to keep the light source 110 on even when the system 100 is turned off (e.g., offline). One or more pumps 134 may be configured to flow the developer solution 101 through the system 100 (e.g., to and from the process tank 102). A heater/cooler 136 may be configured to heat or cool the developer solution 101 according to manufacturing parameters. For example, if a light source 110 heats a developer solution 101 above a threshold temperature, the heater/cooler 136 may cool the developer solution to a temperature below the threshold temperature.

Many of the elements of the system 100 of FIG. 1 are included in other ones of the accompanying drawings; the discussion of these elements is not repeated when discussing these drawings, and any of these elements may take any of the forms disclosed herein. Further, a number of elements are illustrated in FIG. 1 as included in the system 100, but a number of these elements may not be present in a system 100. For example, in various embodiments, a filter 113, a heater/cooler 136, a developer solution waste 108, and a waste stream 109 may not be included.

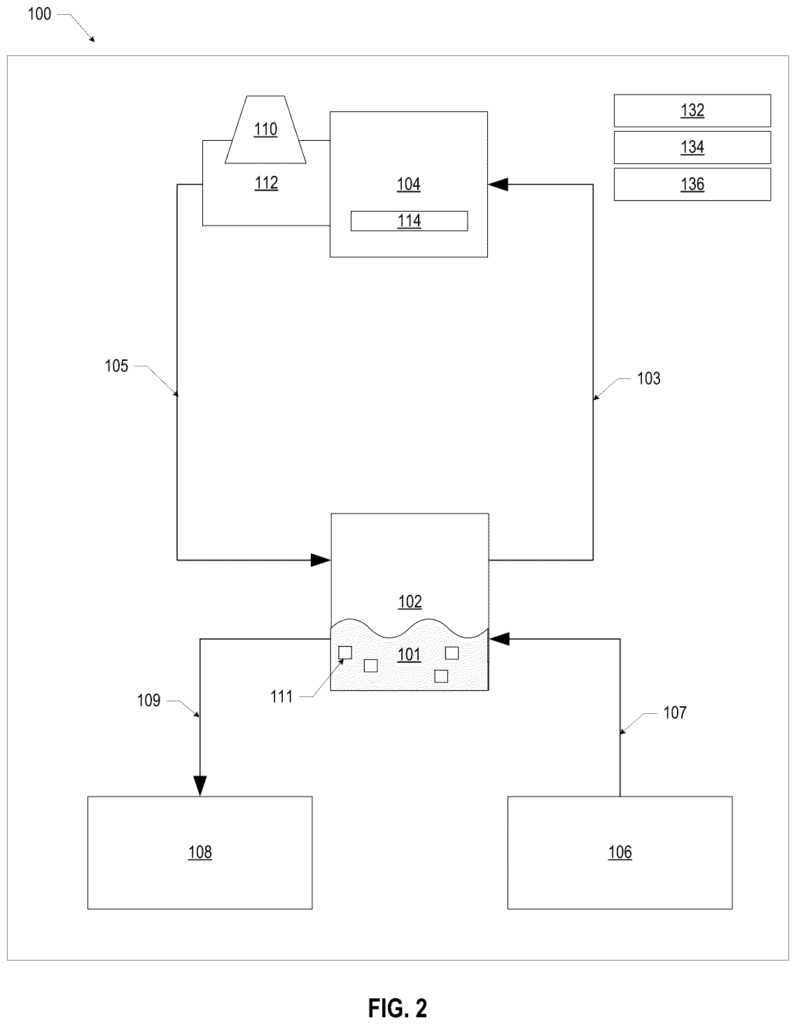

FIG. 2 illustrates an example system 100 for recycling developer solution according to some embodiments of the present disclosure. The configuration of the embodiment shown in the figure is like that of FIG. 1, except for differences as described further. The configuration of system 100 as described herein includes a light chamber 112 with a light source 110 exposing the developer solution 101 to UV/white light. The light chamber 112 may include a box, a container, or another similar structure. In some embodiments, the light chamber 112 may be configured to contain UV/white light from the light source 110 within the light chamber 112. In some embodiments, the light chamber 112 may be configured to hold the developer solution 101 (e.g., for example, a tank or other vessel). The developer solution 101 may be delivered to or flowed through the light chamber 112 before being returned to the process tank 102. The light chamber 112 may be configured to provide sufficient exposure of UV/white light to the recycled developer solution 101. For example, the light chamber 112 may further include structures or components that reduce flow velocity (e.g., narrower or flattened transparent tubing or piping), increase flow distance (e.g., by snaking transparent tubing or piping), and/or increase UV/white light intensity. The light source 110 may be any suitable light source 110, as described above with reference to FIG. 1. In some embodiments, the light source 110 may include a lamp, where the developer solution 101 is funneled to flow past the lamp or deposited as a thin layer on a surface of the lamp. As shown in FIG. 2, the light chamber 112 with the light source 110 may be positioned such that the developer solution 101 is exposed to UV/white light when exiting from the developer chamber 104. In some embodiments, the light chamber 112 may be positioned in a different location within the system 100. Although FIG. 2 shows a system 100 having a single light chamber 112 positioned along a return stream 105, a system 100 may include any suitable number and arrangement of light chambers 112, including one or more, and the light chambers 112 may be positioned in any suitable location within the system 100. Although FIG. 2 shows a system 100 having a single light source 110, a system 100 may have any suitable number and arrangement of light sources 110, including one or more. For example, system 100 in FIG. 2 may also include any of the light sources 110 in FIG. 1 (e.g., 110-1, 110-2, 110-3).

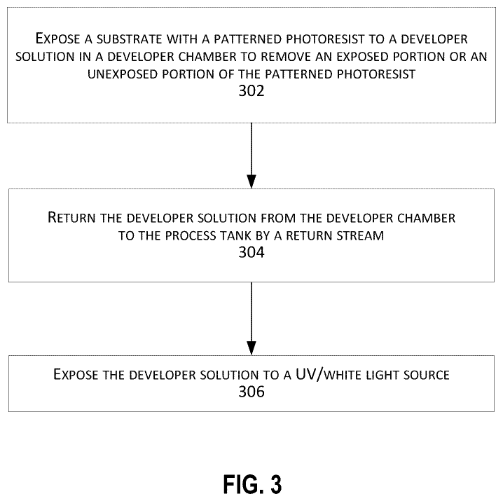

FIG. 3 is a flow diagram of an example method for recycling developer solution according to some embodiments of the present disclosure. At 302, expose a substrate 114 with a patterned photoresist to a developer solution 101 in a developer chamber 104 to remove an exposed portion or an unexposed portion of the patterned photoresist 111. The developer solution 101 may be delivered to the developer chamber 104 from a process tank 102 by a delivery stream 103. The substrate 114 with a patterned photoresist may be exposed to the developer solution 101 using any suitable technique, for example, by a spray nozzle or by immersion. At 304, return the developer solution 101 from the developer chamber 104 to the process tank 102 by a return stream 105. At 306, expose the developer solution 101 to a light source 110. The developer solution 101 may be exposed to the light source 110 while in the process tank 102, while flowing through the return stream 105, while flowing through the delivery stream 103, after exiting from the developer chamber 104, and/or while in a light chamber 112.

The following paragraphs provide various examples of the embodiments disclosed herein.

Example 1 is an apparatus, including a process tank including a developer solution; a developer chamber; a delivery stream coupling the process tank and the developer chamber; a return stream coupling the developer chamber and the process tank; and a light source, wherein the light source is an ultraviolet (UV) light or white light source and is positioned at the process tank, at the delivery stream, or at the return stream.

Example 2 may include the subject matter of Example 1, and may further specify that the light source is positioned at the process tank.

Example 3 may include the subject matter of Example 1, and may further specify that the light source is positioned at the return stream.

Example 4 may include the subject matter of Example 1, and may further specify that the light source is positioned at the delivery stream.

Example 5 may include the subject matter of Example 1, and may further specify that the light source is a first light source positioned at the process tank, and the apparatus and may further include a second light source positioned at the return stream.

Example 6 may include the subject matter of any of Examples 1-5, and may further specify that the light source includes a lamp, an array of lamps, or a string of lights.

Example 7 may include the subject matter of any of Examples 1-6, and may further include a developer solution source vessel including pure developer solution; and a feed stream coupling the developer solution source vessel and the process tank.

Example 8 may include the subject matter of any of Examples 1-7, and may further include a developer solution waste vessel; and a waste stream coupling the developer solution waste vessel and the process tank.

Example 9 may include the subject matter of any of Examples 1-8, and may further include a controller programmed with instructions to turn the light source on and off.

Example 10 may include the subject matter of any of Examples 1-9, and may further include a filter in the return stream or the delivery stream.

Example 11 is an apparatus, comprising a process tank including a developer solution; a developer chamber; a delivery stream coupling the process tank and the developer chamber; a return stream coupling the developer chamber and the process tank; and a light chamber including a light source, wherein the light chamber is positioned along the delivery stream or along the return stream, and the light source is ultraviolet (UV) light or white light.

Example 12 may include the subject matter of Example 11, and may further specify that the light source includes a lamp, an array of lamps, or a string of lights.

Example 13 may include the subject matter of Examples 11 or 12, and may further specify that the light chamber includes flattened, transparent piping.

Example 14 may include the subject matter of Examples 11 or 12, and may further specify that the light chamber includes snaked, transparent piping.

Example 15 is a method, including providing a developer solution to a developer chamber; exposing a substrate having a patterned photoresist in the developer chamber to the developer solution; returning the developer solution to a process tank; and exposing the developer solution to ultraviolet light (UV) light or white light from a light source.

Example 16 may include the subject matter of Example 15, and may further specify that the light source includes a lamp, an array of lamps, or a string of lights.

Example 17 may include the subject matter of Examples 15 or 16, and may further specify that the developer solution is exposed to UV light or white light in the process tank.

Example 18 may include the subject matter of any of Examples 15-17, and may further specify that the developer solution is returned to the process tank by a return stream and the developer solution is exposed to UV light or white light while in the return stream.

Example 19 may include the subject matter of any of Examples 15-18, and may further specify that the developer solution is delivered to the developer chamber from the process tank by a delivery stream and the developer solution is exposed to UV light or white light while in the delivery stream.

Example 20 may include the subject matter of any of Examples 15-19, and may further specify that the developer solution is delivered to a light chamber before being returned to the process tank and the developer solution is exposed to UV light or white light while in the light chamber.

1. An apparatus, comprising:
a process tank including a developer solution;
a developer chamber;
a delivery stream coupling the process tank and the developer chamber;
a return stream coupling the developer chamber and the process tank; and
a light source, wherein the light source is an ultraviolet (UV) light or white light source and is positioned at the process tank, at the delivery stream, or at the return stream.

2. The apparatus of claim 1, wherein the light source is positioned at the process tank.

3. The apparatus of claim 1, wherein the light source is positioned at the return stream.

4. The apparatus of claim 1, wherein the light source is positioned at the delivery stream.

5. The apparatus of claim 1, wherein the light source is a first light source positioned at the process tank, and the apparatus further comprising:
a second light source positioned at the return stream.

6. The apparatus of claim 1, wherein the light source includes a lamp, an array of lamps, or a string of lights.

7. The apparatus of claim 1, further comprising:
a developer solution source vessel including pure developer solution; and
a feed stream coupling the developer solution source vessel and the process tank.

8. The apparatus of claim 1, further comprising:
a developer solution waste vessel; and
a waste stream coupling the developer solution waste vessel and the process tank.

9. The apparatus of claim 1, further comprising:
a controller programmed with instructions to turn the light source on and off.

10. The apparatus of claim 1, further comprising:
a filter in the return stream or the delivery stream.

11. An apparatus, comprising:
a process tank including a developer solution;
a developer chamber;
a delivery stream coupling the process tank and the developer chamber;
a return stream coupling the developer chamber and the process tank; and
a light chamber including a light source, wherein the light chamber is positioned along the delivery stream or along the return stream, and the light source is ultraviolet (UV) light or white light.

12. The apparatus of claim 11, wherein the light source includes a lamp, an array of lamps, or a string of lights.

13. The apparatus of claim 11, wherein the light chamber further includes flattened, transparent piping.

14. The apparatus of claim 11, wherein the light chamber further includes snaked, transparent piping.

15. A method, comprising:
providing a developer solution to a developer chamber;
exposing a substrate having a patterned photoresist in the developer chamber to the developer solution;
returning the developer solution to a process tank; and
exposing the developer solution to ultraviolet light (UV) light or white light from a light source.

16. The method of claim 15, wherein the light source includes a lamp, an array of lamps, or a string of lights.

17. The method of claim 15, wherein the developer solution is exposed to UV light or white light in the process tank.

18. The method of claim 15, wherein the developer solution is returned to the process tank by a return stream and the developer solution is exposed to UV light or white light while in the return stream.

19. The method of claim 15, wherein the developer solution is delivered to the developer chamber from the process tank by a delivery stream and the developer solution is exposed to UV light or white light while in the delivery stream.

20. The method of claim 15, wherein the developer solution is delivered to a light chamber before being returned to the process tank and the developer solution is exposed to UV light or white light while in the light chamber.
